(19) United States
(12) Patent Application Publication
(10) Pub. No.: US 2025/0054905 A1
(43) Pub. Date: Feb. 13, 2025

(54) SEMICONDUCTOR DEVICE, CHIP AND FABRICATION METHOD THEREOF, MEMORY SYSTEM

(71) Applicant: YANGTZE MEMORY TECHNOLOGIES CO., LTD., Wuhan (CN)

(72) Inventors: Ping Mo, Wuhan (CN); Peng Chen, Wuhan (CN); Wei Xie, Wuhan (CN); Hong Fang, Wuhan (CN); Lei Liu, Wuhan (CN); Zhiliang Xia, Wuhan (CN)

(21) Appl. No.: 18/531,542

(22) Filed: Dec. 6, 2023

Related U.S. Application Data
(63) Continuation of application No. PCT/CN2023/111492, filed on Aug. 7, 2023.

(51) Int. Cl. H01L 23/00; H01L 21/822; H10B 80/00

(52) U.S. Cl. CPC H01L 24/97; H01L 21/8221; H10B 80/00; H01L 2224/97; H01L 2924/1438

(57) ABSTRACT

According to one aspect of the present disclosure, semiconductor device is provided. The semiconductor device may include a plurality of cutting lanes. The plurality of cutting lanes may include at least one first cutting lane. The plurality of cutting lanes may include a plurality of second cutting lanes disposed in parallel with the first cutting lane. The plurality of cutting lanes may include a third cutting lane disposed intersecting the first cutting lane and the second cutting lanes. The semiconductor device may include a plurality of dies defined by the intersection of the plurality of cutting lanes. The semiconductor device may include a die test structure only located in the first cutting lane. Any one of the at least one first cutting lane may be disposed adjacent to at least one of the plurality of second cutting lanes.

### CROSS-REFERENCE TO RELATED APPLICATIONS

The present application is a continuation of International Application No. PCT/CN2023/111492, filed on Aug. 7, 2023, the content of which is incorporated herein by reference in its entirety.

### TECHNICAL FIELD

The present disclosure generally relates to electronics, and more particularly to a semiconductor device, a chip and a fabrication method thereof, as well as a memory system.

### BACKGROUND

A Not-And (NAND) memory device is a non-volatile memory product that operates with low power consumption, is light weight, and provides improved performance, which has been widely applied in electronic products. A NAND device of planar structure has practically reached its limit in scalability. In order to further increase memory capacity and reduce memory cost-per-bit, 3D NAND memories are proposed. In a 3D NAND memory architecture, memory cells are arranged in multiple levels stacked vertically to achieve a memory architecture in stack.

### SUMMARY

According to one aspect of the present disclosure, semiconductor device is provided. The semiconductor device may include a plurality of cutting lanes. The plurality of cutting lanes may include at least one first cutting lane. The plurality of cutting lanes may include a plurality of second cutting lanes disposed in parallel with the first cutting lane. The plurality of cutting lanes may include a third cutting lane disposed intersecting the first cutting lane and the second cutting lanes. The semiconductor device may include a plurality of dies defined by the intersection of the plurality of cutting lanes. The semiconductor device may include a die test structure only located in the first cutting lane. Any one of the at least one first cutting lane may be disposed adjacent to at least one of the plurality of second cutting lanes.

In some implementations, at least three of the plurality of second cutting lanes may be arranged between adjacent two of at least one first cutting lane.

In some implementations, a number of the plurality of the second cutting lanes spaced between adjacent two of the at least one first cutting lane may be equal.

In some implementations, a cutting lane of the plurality of cutting lanes may include first dielectric layers second dielectric layers stacked alternatively. In some implementations, the die test structure may penetrate the plurality of cutting lanes in a stacking direction. In some implementations, the die test structure may include third dielectric layers and conductive layers stacked alternatively in the stacking direction.

In some implementations, a thickness of the die test structure may be smaller than or equal to a thickness of the cutting lane.

In some implementations, the die test structure may include a plurality of die test structures. In some implementations, die test structures with a same thickness may be located in a same first cutting lane.

In some implementations, the semiconductor device may further include a semiconductor layer. In some implementations, the semiconductor device may further include a stack on the semiconductor layer, the stack comprising the third dielectric layers and the conductive layers stacked alternatively in the stacking direction. In some implementations, the plurality of cutting lanes and the die test structure may be located on the semiconductor layer.

In some implementations, a die of the plurality of dies may include a memory device and a peripheral circuit bonded with each other. In some implementations, the die test structure may be configured for an electric performance test of the memory device, the peripheral circuit, or a bonding interface between the memory device and the peripheral circuit.

In some implementations, the plurality of cutting lanes and the plurality of dies may form a repeating unit. In some implementations, the repeating unit may include the at least one first cutting lane. In some implementations, the semiconductor device may include a plurality of the repeating units.

According to another aspect of the present disclosure, a chip fabricated from a semiconductor device is provided. The chip may include a stack. The stack may include a plurality of alternating conductive layers and dielectric layers. The stack may include a plurality of channel structures. The chip may include a first cutting face at an outer edge of the stack. The chip may include a second cutting face outside the first cutting face. The second cutting face may have a height smaller than a height of the first cutting face.

According to a further aspect of the present disclosure, a method of fabricating a chip is provided. The method may include providing a semiconductor device provided with a plurality of cutting lanes. The plurality of cutting lanes may include at least one first cutting lane, a plurality of second cutting lanes, and a third cutting lane. The at least one first cutting lane and the plurality of second cutting lanes are disposed in parallel with each other. The third cutting lane may be disposed intersecting the at least one first cutting lane and the plurality of second cutting lanes. A die test structure may be disposed in the first cutting lane. The method may further include cutting the semiconductor device into a plurality of chips along the first cutting lane, the second cutting lane, and the third cutting lane.

In some implementations, the cutting the semiconductor device into a plurality of chips along the at least one first cutting lane, the plurality of second cutting lanes, and the third cutting lane may include cutting the semiconductor device twice with two different cutting processes, respectively.

In some implementations, the cutting the semiconductor device into a plurality of chips along the at least one first cutting lane, the plurality of second cutting lanes, and the third cutting lane may include forming a first groove in the first cutting lane with a first laser to remove a part of the die test structure, wherein a depth of the first groove is smaller than a thickness of the first cutting lane. In some implementations, the cutting the semiconductor device into a plurality of chips along the at least one first cutting lane, the plurality of second cutting lanes, and the third cutting lane may include mechanically cutting the plurality of second cutting lanes, the third cutting lane, and the at least one first cutting lane under the first groove to form a plurality of chips.

In some implementations, before cutting the first cutting lane under the first groove, the plurality of second cutting lanes and the third cutting lane with a blade, the method may further include forming a second groove in the plurality of second cutting lanes and forming a third groove in the third cutting lane with a second laser, wherein a depth of the second groove is smaller than a thickness of the plurality of second cutting lanes, and a depth of the third groove is smaller than a thickness of the third cutting lane. In some implementations, the cutting mechanically the plurality of second cutting lanes, the third cutting lane, and the first cutting lane under the first groove may include cutting the first cutting lane under the first groove, the plurality of second cutting lanes under the second groove and the third cutting lane under the third groove with the blade.

In some implementations, an energy of the second laser is smaller than an energy of the first laser.

In some implementations, the semiconductor device may further include a plurality of dies defined by an intersection of the plurality of cutting lanes. In some implementations, the semiconductor device may further include a die test structure only located in the first cutting lane. In some implementations, any one of the at least one first cutting lane may be disposed adjacent to at least one of the plurality of second cutting lanes.

In some implementations, a cutting lane of the plurality of cutting lanes may include first dielectric layers second dielectric layers stacked alternatively. In some implementations, the die test structure may penetrate the plurality of cutting lanes in a stacking direction. In some implementations, the die test structure may include third dielectric layers and conductive layers stacked alternatively in the stacking direction.

In some implementations a thickness of the die test structure may be smaller than or equal to a thickness of the cutting lane.

In some implementations, at least three of the plurality of second cutting lanes may be arranged between adjacent two of at least one first cutting lane.

In some implementations, a number of the plurality of the plurality of second cutting lanes spaced between adjacent two of the at least one first cutting lane may be equal.

The present disclosure provides a semiconductor device, a chip, and a fabrication method thereof, as well as a memory system. The semiconductor device may include a plurality of cutting lanes, a plurality of dies, and a die test structure. The plurality of dies may be defined by the intersection of the plurality of cutting lanes. The plurality of cutting lanes include at least one first cutting lane, a plurality of second cutting lanes, and a third cutting lane. The first cutting lane and the second cutting lanes may be disposed in parallel with each other, and the third cutting lane may be disposed intersecting the first cutting lane and the second cutting lanes. The die test structure may be only located in the first cutting lane, and any one first cutting lane may be disposed at least adjacent to one of the second cutting lanes. By concentrating the die test structure in the first cutting lane rather than in the second cutting lane and the third cutting lane, it may be possible to use different laser cutting conditions for the cutting lane with the die test structure and the cutting lane without the die test structure while performing cutting process such that the laser cutting depth of the second cutting lane and the third cutting lane is reduced, thereby improving the strength of the device.

### BRIEF DESCRIPTION OF DRAWINGS

Technical solutions and other beneficial effects of the present disclosure will become apparent from the following detailed description of implementations of the present disclosure in connection with the accompanying drawings.

FIG. 1 is a structure diagram of a semiconductor device provided by some implementations of the present disclosure.

FIG. 2 is a structure diagram of a semiconductor device provided by some implementations of the present disclosure.

FIG. 3 is a sectional structure diagram of a semiconductor device in FIG. 1 provided by some implementations of the present disclosure along A-A1.

FIG. 4 is a flow chart of a fabrication method of a chip provided by some implementations of the present disclosure.

FIGS. 5a-5c are structure diagrams of a chip in the fabrication process provided by some implementations of the present disclosure.

FIG. 6 is a structure diagram of a memory system provided by some implementations of the present disclosure.

### DETAILED DESCRIPTION

The technical solutions in implementations of the present disclosure will be described clearly and fully below in connection with accompanying drawings in implementations of the present disclosure. Obviously, the described implementations are only a part of implementations of the present disclosure rather than all of them. All other implementations obtained by those skilled in the art based on the implementations of the present disclosure without any creative works fall within the scope of the present disclosure.

It should be understood that terms “first”, “second” etc. may be used to describe various components herein, but are not intended to limit them. These terms are only used to partition one component from another. For example, a “first component” may be referred to as a “second component” and likewise a “second component” may be referred to as a “first component” without departing from the scope of the present disclosure.

It should be understood that when a component is described to be “on” or “connected to” another component, it can be directly on or connected to the another component or there may be intervening components. Other terms for describing relationship among components should be interpreted similarly.

As used herein, the term “layer” refers to a part of material including a region with a thickness. A layer can extend over the entirety of an underlying or overlying structure or may have an extent less than the extent of an underlying or overlying structure. Furthermore, a layer may be a region of uniform or non-uniform continuous structure with a thickness smaller than that of a continuous structure. For example, a layer may be between the top surface and bottom surface of a continuous structure or between any group of horizontal planes at the top surface and the bottom surface. A layer may extend horizontally, vertically, and/or along a conical surface. The substrate may be a layer that may include one or more layers therein and/or may have one or more layers on, over, and/or under it. A layer can include multiple layers. For example, an interconnect layer can include one or more conductive layers and contact layers (in which contacts, interconnect lines, and/or vertical interconnect accesses (VIA) are formed) and one or more dielectric layers.

It is to be noted that the drawings provided in the implementations of the present disclosure only illustrate the basic conception of the present disclosure schematically. Although only the components related to this disclosure are shown in the drawing, and not drawn according to the number, shape, and size of components in actual implementation, the type, number, and proportion of components in actual implementation can be changed at will, and the layout of components may be more complex.

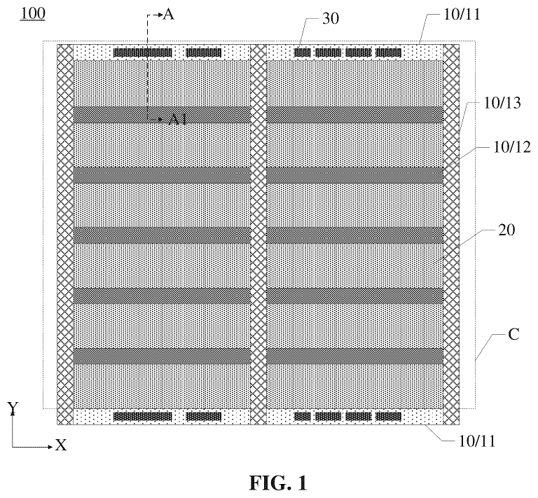

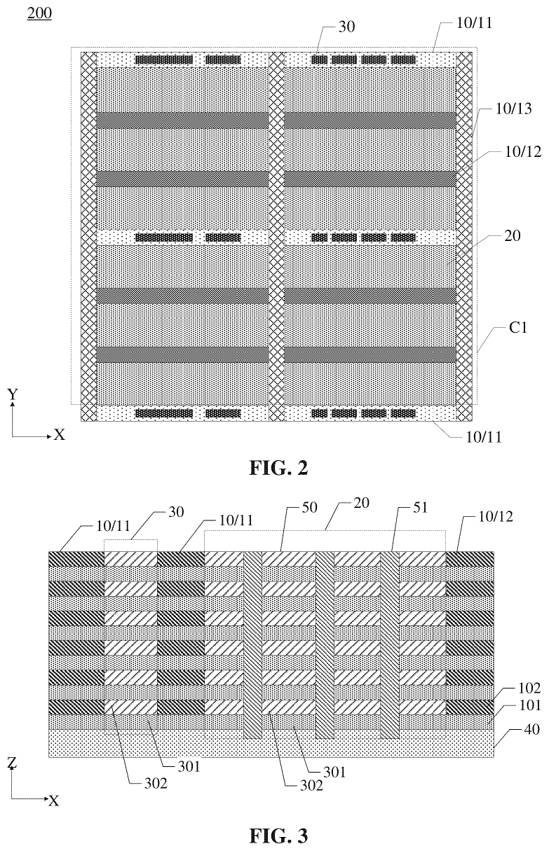

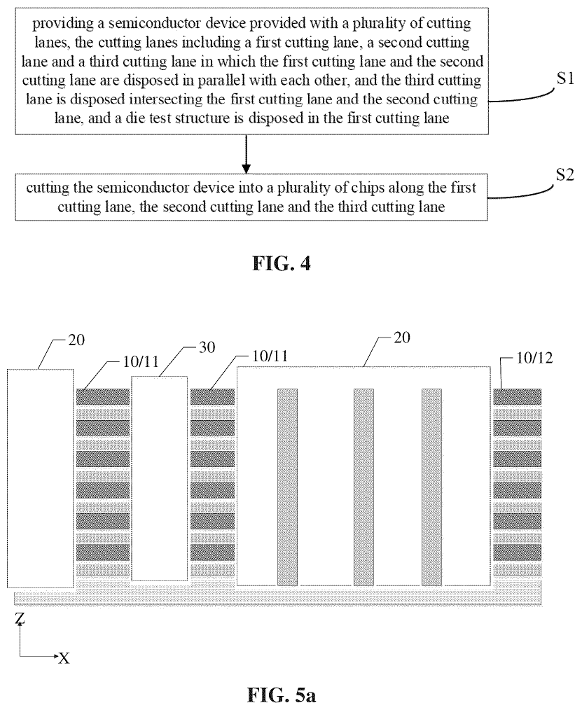

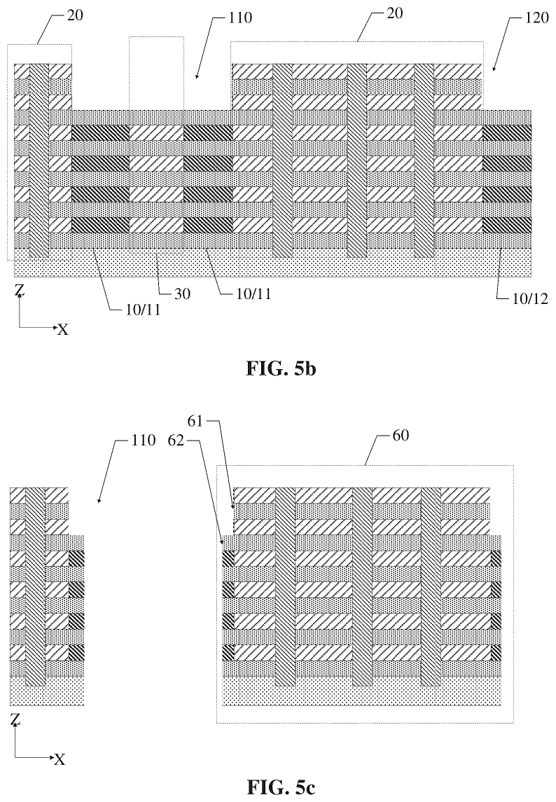

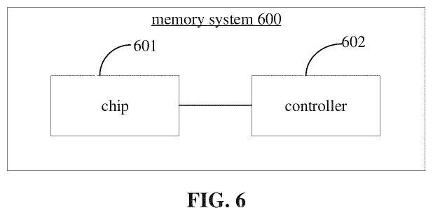

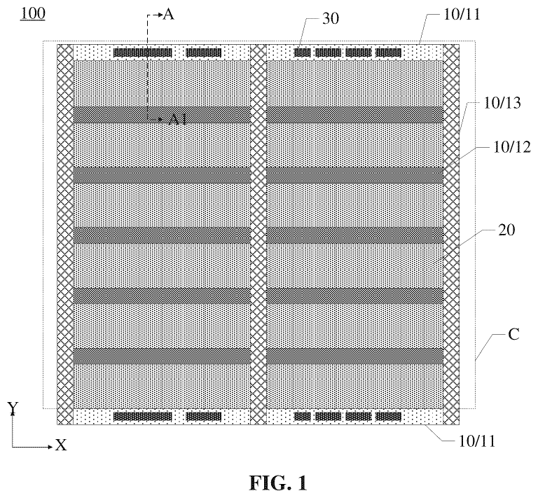

Referring to FIG. 1, a structure diagram of a semiconductor device provided by some implementations of the present disclosure is shown. The semiconductor device 100 may be a wafer, which may be cut to form a plurality of chips, such as a 3D memory. The 3D memory may be applied in communication products, consumer electronic products, automobile products, aerospace products, artificial intelligence products or big data, etc. Consumer electronic products include, but are not limited to mobile phones, computers, tablet computers, cameras, smart glasses, or game products, etc.

The semiconductor device 100 includes a plurality of cutting lanes 10, a plurality of dies 20, and a die test structure 30, in which the plurality of dies 20 are defined by the intersection of the plurality of cutting lanes 10. The plurality of cutting lanes 10 include at least one first cutting lane 11, a plurality of second cutting lanes 12, and a third cutting lane 13 in which the first cutting lane 11 and the second cutting lanes 12 are disposed in parallel with each other. The third cutting lane 13 is disposed intersecting the first cutting lane 11 and the second cutting lanes 12. For example, both the first cutting lane 11 and the second cutting lanes 12 may be disposed in the X direction, and the third cutting lane 13 may be disposed in the Y direction. A plurality of dies 20 are defined by the intersection of the first cutting lane 11, the second cutting lanes 12, and the third cutting lane 13. That is, the dies 20 are located in regions defined by the intersection of the plurality of cutting lanes 10. For example, one die 20 is disposed in one of the regions. As used herein, a “die” may include an integrated circuit block defined by the cutting lanes on the wafer but not cut yet.

The die test structure 30 is only located in the first cutting lane 11. A first cutting lane 11 may be disposed at least adjacent to one of the second cutting lanes 12. That is, the die test structure 30 is concentrated in the first cutting lane 11 and not disposed in the second cutting lanes 12 and the third cutting lane 13. Also, the second cutting lane 12 is disposed besides each first cutting lane 11. For example, one, two, or more of the second cutting lanes 12 are disposed besides each first cutting lane 11. In other words, a cutting lane provided with the die test structure 30 is referred to as the first cutting lane 11, while a cutting lane extending in the same direction of the first cutting lane 11 but not provided with the die test structure 30 is referred to as the second cutting lane 12. In an example, one, two or more of the second cutting lanes 12 are disposed on one side (the side in the Y direction) of each first cutting lane 11, or the second cutting lanes 12 are disposed on both sides (sides in the Y direction) of each first cutting lane 11. The numbers of the second cutting lanes 12 on either side of a first cutting lane 11 may be equal or not equal.

In some implementations, the first cutting lane 11 and the second cutting lanes 12 may be arranged alternatively such that any one first cutting lane 11 is located between two second cutting lanes 12. That is, the first cutting lane 11 is adjacent to the two second cutting lanes 12. In other words, any one first cutting lane 11 is adjacent to a second cutting lane 12 on either side, respectively.

In some implementations, at least three second cutting lanes 12 may be disposed between adjacent two first cutting lanes 11. As shown in FIG. 1, any one first cutting lane 11 is disposed adjacent to five second cutting lanes 12 and five second cutting lanes 12 are disposed between adjacent two first cutting lanes 11.

In some implementations, a plurality of cutting lanes 10 and a plurality of dies 20 may constitute a repeating unit C for mask exposure, which refers to the process of patterning the underlying structure via a mask, including photolithography process. The repeating unit C includes at least one first cutting lane 11 and the semiconductor device 100 includes a plurality of the repeating units C.

FIG. 1 shows one repeating unit C, which implies that the integrated circuit pattern in the semiconductor device 100 is obtained by repeating the repeating unit C in at least one of the X direction or the Y direction. It is appreciated that a first cutting lane 11 is also provided under the bottom die 20 in FIG. 1, but the first cutting lane 11 belongs to another repeating unit. It is also appreciated that the first cutting lane 11 at the lower part of FIG. 1 belongs to the repeating unit C while the first cutting lane 11 at the upper part of FIG. 1 belongs to another repeating unit. One repeating unit C may be formed by one mask, and 12 dies 20 shown in FIG. 1 may be formed with one mask.

As shown in FIG. 1, one repeating unit C may include one first cutting lane 11 and five second cutting lanes 12, and the first cutting lane 11 may be disposed on one side of the five second cutting lanes 12. In other implementations, the first cutting lane 11 may also be between any two second cutting lanes 12. It is to be noted that the numbers of cutting lanes 10 in the present disclosure are only examples, and the numbers of the cutting lanes 10, the first cutting lane 11 and the second cutting lanes 12 are not limited to those depicted in the figures.

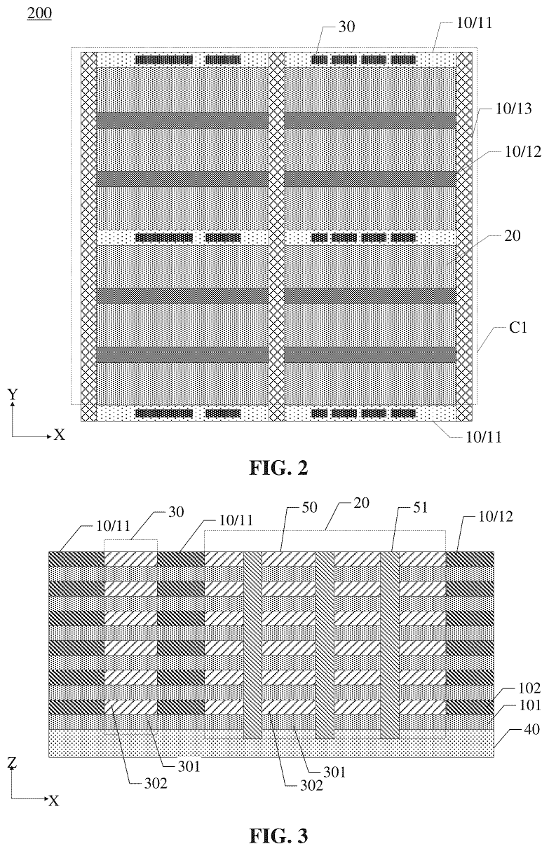

Referring to FIG. 2, a structure diagram of a semiconductor device provided by some implementations of the present disclosure is shown. One repeating unit Cl is shown in the semiconductor device 200 in FIG. 2, and the repeating unit Cl includes two first cutting lanes 11 and four second cutting lanes 12. That is, in case there are a plurality of die test structures 30, and the die test structures 30 may be concentrated in the two first cutting lanes 11.

In some implementations, in case there are a plurality of die test structures 30, the die test structures 30 may be concentrated in more than two first cutting lanes 11.

In some implementations, the number of second cutting lanes 12 spacing between two adjacent first cutting lanes 11 is equal, such that it can guarantee the distribution of die test structures 30 is uniform and the stress may be averaged. For example, there may be two second cutting lanes 12 between two adjacent first cutting lanes 11.

Referring to FIG. 3, a sectional structure diagram of the semiconductor device in FIG. 1 provided by some implementations of the present disclosure along A-A1 is shown.

The cutting lane 10 may include first dielectric layers 101 and second dielectric layers 102 stacked alternatively, and the die test structure 30 penetrates the cutting lane 10 in the stacking direction (Z) of the cutting lane 10 and may include third dielectric layers 301 and conductive layers 302 stacked alternatively in the stacking direction (Z).

The materials for the first dielectric layer 101 and the second dielectric layer 102 may include, but are not limited to, e.g., silicon oxide, silicon nitride, or silicon oxynitride, just to name a few. The materials for the first dielectric layer 101 and the second dielectric layer 102 may be different. The material for the third dielectric layer 301 may include, but is not limited to, silicon oxide, silicon nitride, or silicon oxynitride, of which the example material may be silicon oxide. The third dielectric layer 301 may have the same material as the first dielectric layer 101 or the second dielectric layer 102. For example, both the third dielectric layers 301 and the first dielectric layers 101 may be silicon oxide and are disposed on the same layer, and the conductive layer 302 and the second dielectric layer 102 may be disposed on the same layer. Alternatively, both the third dielectric layer 301 and the second dielectric layer 102 may be silicon oxide and disposed on the same layer, and the conductive layer 302 and the first dielectric layer 101 may be disposed on the same layer.

The conductive layer 302 may include one or more conductive materials such as tungsten, titanium carbide, poly-crystalline silicon, etc. The conductive layers 302 may further include a high-k material such as aluminum oxide.

The semiconductor device 100 may further include a semiconductor layer 40 and a stack 50 on the semiconductor layer 40. The stack 50 may include third dielectric layers 301 and conductive layers 302 stacked alternatively in the stacking direction (Z). The cutting lane 10 and the die test structure 30 may be located on the semiconductor layer 40. A die 20 may include the stack 50 and some channel structures 51, and the die 20 (or the stack 50) may be adjacent to the first cutting lane 11 and the second cutting lane 12.

In some implementations, the thickness of the cutting lane 10 may be equal to the thickness of the stack 50. It is appreciated that the “thickness” in the present disclosure refers to the thickness in Z direction.

In some implementations, the thickness of the die test structure 30 is smaller than or equal to the thickness of the cutting lane 10.

In some implementations, the thickness of each of all the die test structures 30 is smaller than the thickness of the cutting lane 10, or the thickness of each of all the die test structures 30 is equal to the thickness of the cutting lane 10.

In some implementations, the thickness of some die test structures 30 is smaller than the thickness of the cutting lane 10 and the thickness of other die test structures 30 is equal to the thickness of the cutting lane 10.

The die 20 may further include a memory device and a peripheral circuit (not shown in the figures) bonded with each other. In some implementations, the die 20 may be a memory (NAND) grain, and the peripheral circuit may be a complementary metal oxide semiconductor (CMOS). The peripheral circuit is electrically connected with the memory device to transfer signals with the memory device. The peripheral circuit may be configured to implement logical operations and control and detect on-off states of memory cells in the memory device via metal lines for data storing and reading.

The die test structure 30 may be configured for electric performance test of the memory device, the peripheral circuit, or the bonding interface between the memory device and the peripheral circuit. For example, the die test structure 30 may be configured to test electric performance of memory cells in the memory device, test electric performance of transistors in the peripheral circuit, and test electrical connection of the bonding interface.

In some implementations, it is possible to separate the plurality of dies 20 to obtain a plurality of chips by cutting the semiconductor device 100 along the first cutting lane 11, the second cutting lanes 12, and the third cutting lane 13. Cutting processes may include laser cutting and mechanical cutting.

As the number of layers of the stack 50 increase, the number of conductive layers 302 in the die test structure 30 also increase. That is, the thickness of the die test structure 30 increases. If the die test structures 30 are distributed in the first cutting lane 11 and the second cutting lane 12 in a scattered arrangement, they may also be distributed in the third cutting lane 13. If only one or two die test structures 30 are disposed in one cutting lane 10, then the cutting lane 10 has different materials at the location with the die test structure 30 and at the location without the die test structure 30. While laser scan cutting is performed along the cutting lane 10, since it is difficult to adjust the output power of the laser in scanning cutting of the same cutting lane 10, different depths are formed by cutting at different locations. In an example, the cutting depth at a location without the die test structure 30 is deeper than the cutting depth at a location with the die test structure 30. A laser cutting depth that is undesirably deep may result in degraded strength of the device.

In the semiconductor device provided by implementations of the present disclosure, the die test structures 30 are concentrated in the first cutting lane 11 and there is no die test structure 30 in the second cutting lanes 12 and the third cutting lane 13. Thus, it is possible to process the first cutting lane 11 with different laser settings while cutting. For example, the laser energy for the second cutting lanes 12 and the third cutting lane 13 may be adjusted such that it is smaller than the laser energy for the first cutting lane 11 (even 0), thereby achieving a better consistency of the laser cutting depth for the cutting lanes 10. That is, for the second cutting lanes 12 and the third cutting lane 13 without die test structure 30, it may be possible to reduce their laser cutting depth to improve the degradation of the strength of device due to laser cutting. Further, the chip can undergo a greater bending force during the packaging process, thereby reducing the break risk of the chip.

In some implementations, the die test structures 30 are disposed in the first cutting lane 11 and not disposed at the intersection of the first cutting lane 11 and the third cutting lane 13. As such, different cutting conditions may be used for the first cutting lane 11 and the third cutting lane 13 to achieve a better consistency of cutting depth.

In some implementations, it may be possible to dispose the die test structures 30 with the same thickness in the same first cutting lane 11. For example, the die test structures 30 with a bigger thickness are disposed in one first cutting lane 11, and the die test structures 30 with a smaller thickness are disposed in another first cutting lane 11.

As compared to the first cutting lane 11 in which thicker die test structures 30 are disposed, the laser cutting condition for the first cutting lane 11 in which thinner die test structures 30 are disposed is adjusted such that the laser energy is smaller, which can achieve an improved consistency of cutting depth for both. It may be also possible to reduce the cutting depth of the first cutting lane 11 in which thinner die test structures 30 are disposed to improve the strength of device.

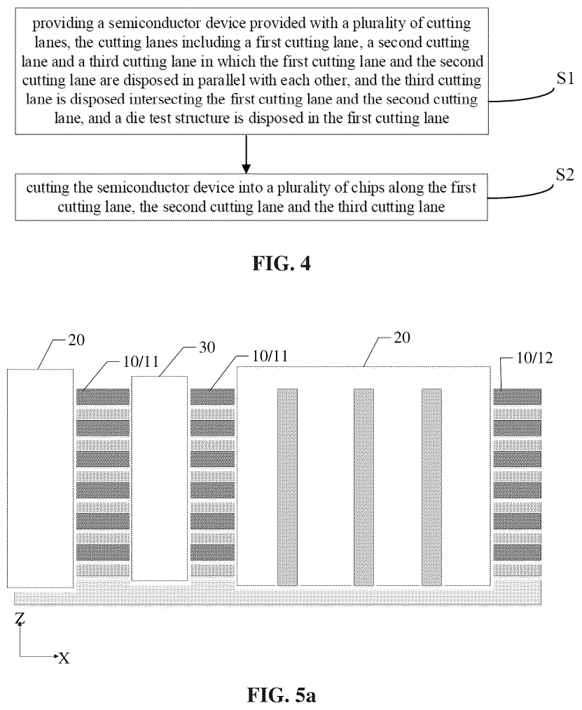

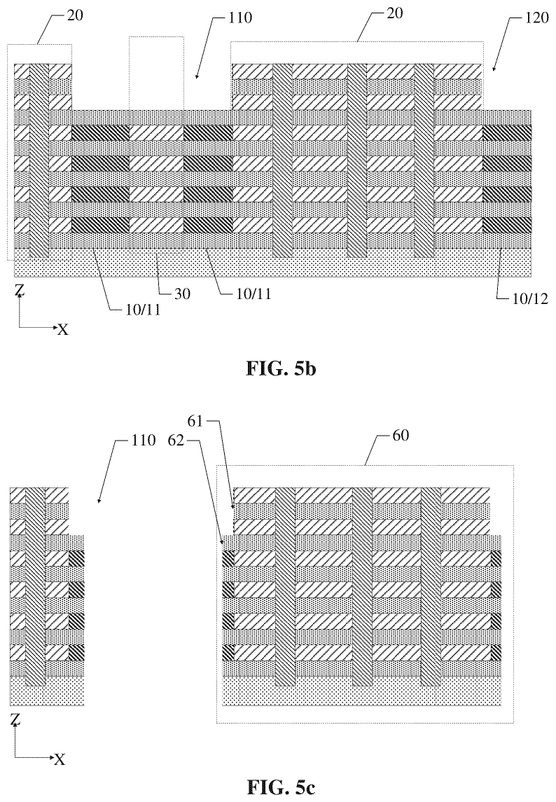

Referring to FIG. 4, a flow chart of a fabrication method of a chip provided by some implementations of the present disclosure is shown. Referring to FIGS. 5a-5c, structure diagrams of a chip in the fabrication process provided by some implementations of the present disclosure is shown. The chip is obtained by cutting the above-described semiconductor device 100, and thus FIGS. 1 and 3 may be referred to below in the description of FIGS. 4 and 5a-5c. The fabrication of the chip may include the following operations S1-S2.

Referring to FIG. 4, at operation S1, the method may include providing a semiconductor device provided with a plurality of cutting lanes 10, the cutting lanes 10 including a first cutting lane 11, a second cutting lane 12 and a third cutting lane 13 in which the first cutting lane 11 and the second cutting lane 12 are disposed in parallel with each other, and the third cutting lane 13 is disposed intersecting the first cutting lane 11 and the second cutting lane 12, and a die test structure 30 is disposed in the first cutting lane 11. For example, referring to FIG. 1, in one repeating unit C, the die test structures 30 are concentrated in one first cutting lane 11. As shown in FIG. 5a, the die 20 is located between two first cutting lanes 11, or between the first cutting lane 11 and the second cutting lane 12.

Referring again to FIG. 4, at operation S2, the method may include cutting the semiconductor device into a plurality of chips 60 along the first cutting lane 11, the second cutting lane 12 and the third cutting lane 13. In some implementations, it is possible to cut the semiconductor device twice with two different cutting processes. For example, a groove is formed on the front face of the device with laser cutting, and then the semiconductor device is completely cut with a machine such as a blade. Laser cutting may make the cutting edge on the front face of device smoother, thereby improving the quality of the front face of the chips 60. As shown in FIG. 5b, it is possible to form a first groove 110 in the first cutting lane 11 with a first laser to remove a part of the die test structure 30, wherein the depth of the first groove 110 is smaller than the thickness of the first cutting lane 11. As shown in FIG. 5c, then the second cutting lane 12, the third cutting lane 13, and the first cutting lane 11 under the first groove 110 are cut mechanically to form a plurality of chips 60. That is, the first cutting lane 11 may be cut once with laser to form the groove, while the second cutting lane 12 and the third cutting lane 13 are not cut with laser, and then the first cutting lane 11, the second cutting lane 12 and the third cutting lane 13 are cut mechanically once to cut the semiconductor device into a plurality of chips 60. Therefore, such cutting manner can realize local laser cutting and low-cost high output.

In some implementations, it is also possible to form a second groove 120 in the second cutting lane 12 with a second laser and form a third groove (not shown) in the third cutting lane 13 before performing the described-above mechanical cutting, wherein the depth of the second groove 120 is smaller than the thickness of the second cutting lane 12, and the depth of the third groove is smaller than the thickness of the third cutting lane 13.

Since there is no die test structure 30 in the second cutting lane 12 and the third cutting lane 13, setting the energy of the second laser to be smaller than the energy of the first laser may allow the depth of the second groove 120 and the third groove to be consistent with the depth of the first groove 110. That is, in the case of laser cutting, the laser cutting depth of the second cutting lane 12 and the third cutting lane 13 is reduced to improve the strength of the chips 60.

In some implementations, it may be possible to reduce the number of burnings with the second laser (smaller than the number of burnings with the first laser) such that the depth of the second groove 120 and the third groove is consistent with the depth of the first groove 110. In case that the second cutting lane 12 and the third cutting lane 13 are not cut with laser, or the number of burnings with laser is small, it is possible to reduce the laser burning time required for the entire semiconductor device and improve the unit time output.

It is appreciated that as shown in FIG. 1, since the die test structures 30 do not cover the first cutting lane 11 completely, there are intervals between the die test structures 30. Therefore, the cutting depth in the die test structures 30 will be smaller than the laser cutting depth at the intervals while cutting the first cutting lane 11 with laser scanning.

With the fabrication method of chips provided by implementations of the present disclosure, since the die test structures 30 are concentrated in the first cutting lane 11, it is possible to use different parameters for the first cutting lane 11 than the second cutting lane 12 and the third cutting lane 13 to reduce the laser cutting depth of the second cutting lane 12 and the third cutting lane 13, thereby improving strength of chips 60.

An implementation of the present disclosure further provides a chip fabricated from the semiconductor device of any one of the above-described implementations. Referring to FIG. 5c, the chip includes a first cutting face 61 and a second cutting face 62 outside the first cutting face 61, and the second cutting face 62 has a height in Z direction smaller than the height of the first cutting face 61 in Z direction.

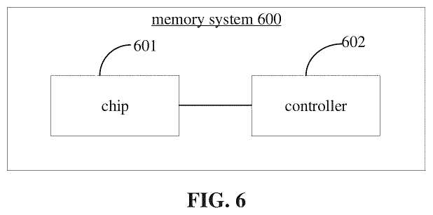

Referring to FIG. 6, a structure diagram of a memory system provided in some implementations of the present disclosure is shown. The memory system 600 may include a chip 601 and a controller 602. The chip 601 may be the chip in any of the above-described implementations and may be fabricated from the semiconductor device in the above-described implementations. The controller 602 is electrically connected with the chip 601 to control the chip 601 to store data and the chip 601 may execute data storage operations based on the controller's 602 control.

In some implementations, the memory system may be implemented as multimedia card such as universal flash storage (UFS) device, solid state hard disk (SSD), MMC, eMMC, RS-MMC and mini-MMC, secure digital card such as SD, mini-SD and micro-SD, storage device of Personal Computer Memory Card International Association (PCMCIA) type, storage device of peripheral component interconnect (PCI) type, storage device of PCI Express (PCI-E) type, compact flash (CF) card, smart media card or memory stick, etc.

Description of the implementations above is only used to facilitate understanding of the technical solutions and the core concept of the present disclosure. It can be understood by those of ordinary skills in the art that the technical solutions described in the foregoing various implementations can be modified or have some technical features therein replaced equivalently without departing from the spirit and scope of the technical solutions in the implementations of the present disclosure.

What is claimed is:

1. A semiconductor device comprising:
a plurality of cutting lanes, comprising:
at least one first cutting lane;
a plurality of second cutting lanes disposed in parallel with the first cutting lane; and
a third cutting lane disposed intersecting the first cutting lane and the second cutting lanes;
a plurality of dies defined by the intersection of the plurality of cutting lanes; and
a die test structure only located in the first cutting lane,
wherein any one of the at least one first cutting lane is disposed adjacent to at least one of the plurality of second cutting lanes.

2. The semiconductor device of claim 1, wherein at least three of the plurality of second cutting lanes are arranged between adjacent two of at least one first cutting lane.

3. The semiconductor device of claim 1, wherein a number of the plurality of the second cutting lanes spaced between adjacent two of the at least one first cutting lane is equal.

4. The semiconductor device of claim 1, wherein:
a cutting lane of the plurality of cutting lanes comprises first dielectric layers second dielectric layers stacked alternatively,
the die test structure penetrates the plurality of cutting lanes in a stacking direction, and
the die test structure comprises third dielectric layers and conductive layers stacked alternatively in the stacking direction.

5. The semiconductor device of claim 4, wherein a thickness of the die test structure is smaller than or equal to a thickness of the cutting lane.

6. The semiconductor device of claim 5, wherein:
the die test structure comprises a plurality of die test structures, and
die test structures with a same thickness are located in a same first cutting lane.

7. The semiconductor device of claim 4, further comprising:
a semiconductor layer; and
a stack on the semiconductor layer, the stack comprising the third dielectric layers and the conductive layers stacked alternatively in the stacking direction,
wherein the plurality of cutting lanes and the die test structure are located on the semiconductor layer.

8. The semiconductor device of claim 1, wherein:
a die of the plurality of dies comprises:
a memory device and a peripheral circuit bonded with each other, and
the die test structure is configured for an electric performance test of the memory device, the peripheral circuit, or a bonding interface between the memory device and the peripheral circuit.

9. The semiconductor device of claim 1, wherein:
the plurality of cutting lanes and the plurality of dies form a repeating unit,
the repeating unit comprises the at least one first cutting lane, and
the semiconductor device comprises a plurality of the repeating units.

10. A chip fabricated from a semiconductor device, comprising:
a stack, comprising:
a plurality of alternating conductive layers and dielectric layers; and
a plurality of channel structures;
a first cutting face at an outer edge of the stack; and
a second cutting face outside the first cutting face,
wherein the second cutting face has a height smaller than a height of the first cutting face.

11. A method of fabricating a chip, comprising:
providing a semiconductor device provided with a plurality of cutting lanes, the plurality of cutting lanes comprising at least one first cutting lane, a plurality of second cutting lanes, and a third cutting lane, wherein the at least one first cutting lane and the plurality of second cutting lanes are disposed in parallel with each other, and the third cutting lane is disposed intersecting the at least one first cutting lane and the plurality of second cutting lanes, and a die test structure is disposed in the first cutting lane; and
cutting the semiconductor device into a plurality of chips along the first cutting lane, the second cutting lane, and the third cutting lane.

12. The method of claim 11, wherein the cutting the semiconductor device into a plurality of chips along the at least one first cutting lane, the plurality of second cutting lanes, and the third cutting lane comprises:
cutting the semiconductor device twice with two different cutting processes, respectively.

13. The method of claim 12, wherein the cutting the semiconductor device into a plurality of chips along the at least one first cutting lane, the plurality of second cutting lanes, and the third cutting lane comprises:
forming a first groove in the first cutting lane with a first laser to remove a part of the die test structure, wherein a depth of the first groove is smaller than a thickness of the first cutting lane; and
mechanically cutting the plurality of second cutting lanes, the third cutting lane, and the at least one first cutting lane under the first groove to form a plurality of chips.

14. The method of claim 13, wherein:
before cutting the first cutting lane under the first groove, the plurality of second cutting lanes and the third cutting lane with a blade, the method further comprises:
forming a second groove in the plurality of second cutting lanes and forming a third groove in the third cutting lane with a second laser, wherein a depth of the second groove is smaller than a thickness of the plurality of second cutting lanes, and a depth of the third groove is smaller than a thickness of the third cutting lane; and
the cutting mechanically the plurality of second cutting lanes, the third cutting lane, and the first cutting lane under the first groove comprises:
cutting the first cutting lane under the first groove, the plurality of second cutting lanes under the second groove and the third cutting lane under the third groove with the blade.

15. The method of claim 14, wherein an energy of the second laser is smaller than an energy of the first laser.

16. The method of claim 11, wherein the semiconductor device further comprises:
a plurality of dies defined by an intersection of the plurality of cutting lanes; and
a die test structure only located in the first cutting lane,
wherein any one of the at least one first cutting lane is disposed adjacent to at least one of the plurality of second cutting lanes.

17. The method of claim 16, wherein:
a cutting lane of the plurality of cutting lanes comprises first dielectric layers second dielectric layers stacked alternatively,
the die test structure penetrates the plurality of cutting lanes in a stacking direction, and
the die test structure comprises third dielectric layers and conductive layers stacked alternatively in the stacking direction.

18. The method of claim 17, wherein a thickness of the die test structure is smaller than or equal to a thickness of the cutting lane.

19. The method of claim 11, wherein at least three of the plurality of second cutting lanes are arranged between adjacent two of at least one first cutting lane.

20. The method of claim 11, wherein a number of the plurality of the plurality of second cutting lanes spaced between adjacent two of the at least one first cutting lane is equal.
